(19) United States
(12) Patent Application Publication
(10) Pub. No.: US 2011/0042709 A1
(43) Pub. Date: Feb. 24, 2011

(54) Free-standing mounted light emitting diodes for general lighting

(76) Inventors: Christoph Stark, Troy, NY (US); Christian Wetzel, Troy, NY (US); Theeradetch Detchprohm, Niskayuna, NY (US)

Correspondence Address: Alexey Kudymov, 3 Granite Ln, Troy, NY, 12180, US

(21) Appl. No.: 12/857,760

(22) Filed: Aug. 17, 2010

Related U.S. Application Data
(60) Provisional application No. 61/234,839, filed on Aug. 18, 2009.

(51) Int. Cl. H01L 33/62

(52) U.S. Cl. 257/99; 257/E33.066

(57) ABSTRACT

The current invention introduces a semiconductor light emitting device mounted in a free-standing way for enhanced light extraction and handling simplicity. The free-standing mount is based on the mechanical strength of the current carrying connectors, such as wires or bonds. Such mounted LED die can be placed into standard light bulb body for compatibility with existing household, car, consumer electronics or industrial light sources. The current invention provides increased light extraction efficiency which makes general LED lighting simpler and cheaper. The mounting into a conventional light bulb provides the consumer with the ease of handling and mounting.

### CROSS-REFERENCE TO RELATED APPLICATION

This application claims the benefit of Provisional Patent Application Ser. No. 61/234,839, filed Aug. 18, 2009 by present inventors.

### FEDERALLY SPONSORED RESEARCH

Not Applicable

### SEQUENCE LISTING OR PROGRAM

Not Applicable

### FIELD OF THE DISCLOSURE

Aspects of the invention relate generally to solid state light sources such as semiconductor light emitting diodes, and more particularly, to a light emitting diode die mounted directly on the electrical current carrying wires.

### BACKGROUND OF THE DISCLOSURE

Solid state lighting with light-emitting diodes (LEDs) is a rapidly growing market. Nevertheless it has not replaced conventional incandescent lightning due to several factors like cost, unpleasant light color, or undesirable light emission patterns. Currently, there are LED lamps available that are designed for normal household sockets, and these lamps use state-of-the-art LEDs. Today, most LEDs for lighting applications are top surface or back surface emitting, where the light is extracted through a plane parallel to the active region in which the light is generated. The light generation is isotropic and the light therefore has no preferred propagation direction.

A simple state-of-the-art LED comprises a substrate, a region of one major carrier type (n- or p-type), one or more regions with different doping levels, dopants or alloy concentrations, one or more active regions, and one region of major carrier type opposite to that of the first one. Metallic contacts are normally used to electrically connect the said LED to a source of current. State-of-the-art LEDs are designed to provide a maximum light output through one of the sides that are parallel to the active region.

In order to connect an LED die to the electrical and mechanical holder, many connection schemes are used, including direct wiring to transparent front- or back-side contacts, flip-chip mountings, substrate removal, or similar. The LED die is usually mechanically mounted onto a heat-sink which is typically metallic and non-transparent. Without any further constructions, light which is emitted in the direction of the heat-sink is lost. Therefore various methods for redirecting this light have been used, like back-side reflectors made of metallic or dielectric mirrors. Despite efforts, these reflectors are not perfect, due to absorption, reflection to undesired direction, or other loss mechanisms and are cause for lower device efficiency. What is needed is an approach to use most of the generated light right away. This will improve efficiency of the LED lighting device and reduce costs in manufacturing.

The LEDs referred to in this disclosure can be based on any suitable material system, including but not limited to the common GaN, GaInN, AlGaN, and GaAs material systems and alloys thereof.

The dies on which these LEDs are fabricated can be arbitrary shaped. Common shapes include, but are not limited to, circular, segment of circle, rectangular, or other polygonal shapes. The dies do not necessarily need to be flat, but other geometries are possible, including, but not limited to curved, bowed, extruded, or spherical surfaces.

### SUMMARY OF THE INVENTION

Aspects of the invention are directed to semiconductor light emitting devices mounted directly onto the electrical current carrying wires for increased light extraction.

An objective of present invention is to provide a method for building a lighting device that makes use of free-standing mounted LEDs to improve the current technology in aspects of—including, but not limited to—light extraction efficiency, ease of handling, ease of mounting, user-friendly handling and cost reduction.

According to the present invention this can be achieved by mounting one or more LEDs fabricated on one or more dies in a free-standing way and relinquish from using a reflector or heat-sink on the front or back side of the LEDs. By doing so, the light emission through the top and the back surface, as well as through one or more of the side surfaces can contribute to the total light output of the device or assembly.

Free-standing mount of an LED die, for the purpose of present invention, means that there is no overlap by a mechanical holder or a heat sink, except heat exchange agent such as gas or liquid, immediately adjacent to the said LED die, of the entire light path from one or more sides of the LED die, or a significant portion of the said light path. It is understood that in case of the light extraction, significant portion of the light path means that the extraction efficiency is affected by 10% of its value for unmounted die or more for the said side, or by 1% of its value for unmounted die or more for the total extraction efficiency. LED die is a whole or a portion thereof of the substrate with semiconductor structure on it as fabricated including interconnect and contact metals deposited, but excluding connections to the parts and/or objects not fabricated or mounted on the same substrate.

In a first aspect of the present invention, one or more LED dies are mounted on the inside of a light bulb that has the fundamental properties of conventional incandescent light bulb, but instead of a filament an LED die is used for light generation.

In a second aspect of the present invention, the two or more free-standing mounted LED dies that have asymmetric light emission patterns from one or more sides of the dies, are mounted free-standing, as described above with the corresponding side facets arranged in space in pre-defined way with respect to each other, in order to form a combined emission pattern. In this way the light emission of the ensemble can be made, for example, nearly uniform in all directions, or nearly symmetric in the directions perpendicular to the said side facets (two or more) of the dies. For more complicated emission patterns from a single die, or in case a specific total emission pattern is desired, the LEDs may be mounted arbitrarily with respect to each other in order to obtain the said desired collective emission pattern.

In a third aspect of the present invention, the said LEDs, or the said LED dies themselves are configured in such a way that they can directly operate at the customers normal household outlet voltage. This increases the ease of use and reduces loss mechanisms that occur in state-of-the art transformers and LED drivers.

### BRIEF DESCRIPTION OF THE DRAWINGS

These and other features of the present invention will be more readily understood from the following brief description of the various aspects of the invention taken in conjunction with the accompanying drawings, in which:

FIG. 1 depicts an LED die mounted into the standard conventionally shaped light bulb using the electric current carrying wires connected to the same surface of the said die, according to an embodiment.

FIG. 2 depicts an LED die mounted into the standard conventionally shaped light bulb using the electric current carrying wires connected to the opposite surfaces of the said die, according to an embodiment.

FIG. 3 depicts an LED mount of FIG. 1 with different die orientation with respect to the bulb base.

FIG. 4 depicts an example of combined mechanical support and electrical connection of a sector-shaped die.

It is noted that the drawings of the invention are not to scale. The drawings are intended to depict only typical aspects of the invention, and therefore should not be considered as limiting the scope of the invention.

### DETAILED DESCRIPTION

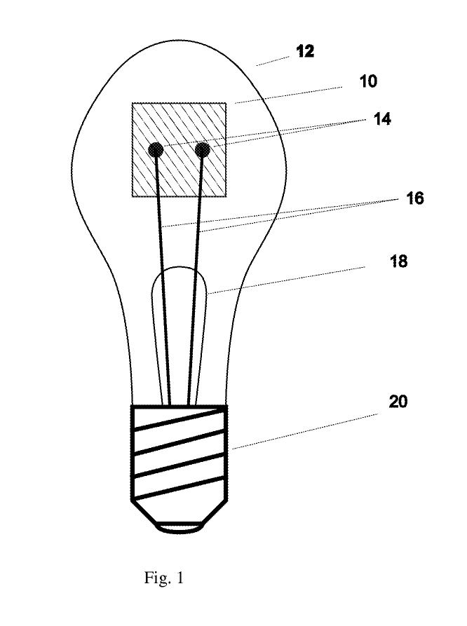

FIG. 1 depicts an LED die 10, mounted inside the standard, conventionally shaped glass body light bulb 12 in accordance with an embodiment. The said LED die 10 is connected using electrically conductive contacts 14 to the current carrying wires 16 having appropriate mechanical strength to support the LED die 10 inside the bulb body. This mechanical strength of the said wires 16 is further enhanced by glass pedestal 18 of the standard light bulb body, attached to the bulb base 20. The body of the light bulb 12 can be further filled with a gas or liquid for the purposes of heat transfer, chemical stability of the assembly or any other purpose distinguishable by a skilled artisan. The wires 16 have electrical connection to the external electrodes of the bulb base 20, either directly or through the driver circuit comprised within the said bulb base 20.

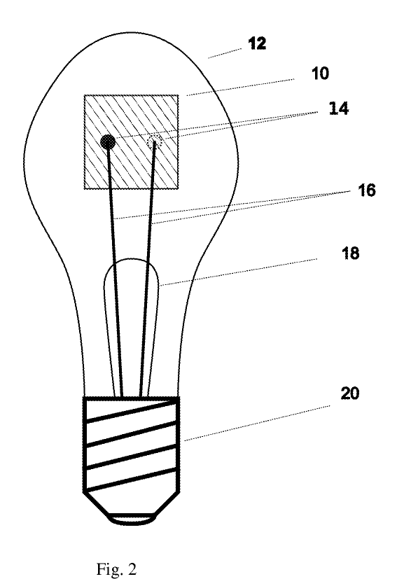

As a result of the arrangement of FIG. 1, the two wires 16 that are coming from the bulb base 20, are connected to the appropriate contacts 14 on the LED die. There can be more than two wires, some of them serving as electrical contacts, some as mechanical support for the structure, some as thermal connections, or a combination thereof. The wires can be attached on either side of the LED die, as provided by FIG. 2, or in a combination thereof.

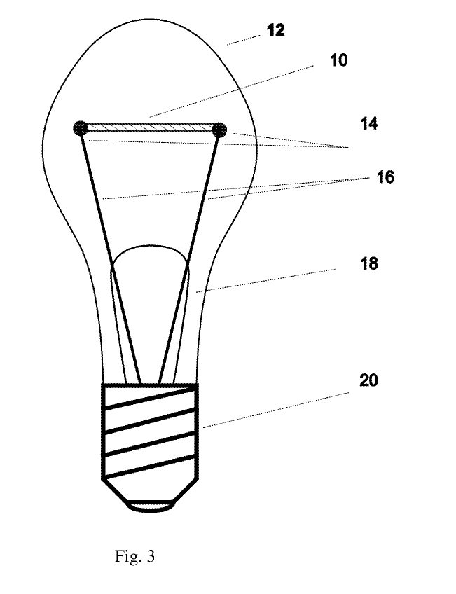

Depending upon LED die shape, light extraction directivity diagram and specific application, the person skilled in the art may choose different chip orientation with respect to the bulb body. In FIG. 3, the supporting and current carrying wires 16 are arranged perpendicular to the LED active area plain, allowing the light coming out of the top surface of an LED die 10 to be directed in the bulb symmetry axis. Such a mount can be preferred where the directed light is needed, for example in automotive applications, for flashlights or personal light sources (as used in cars, buses, airplanes, table lamps etc.)

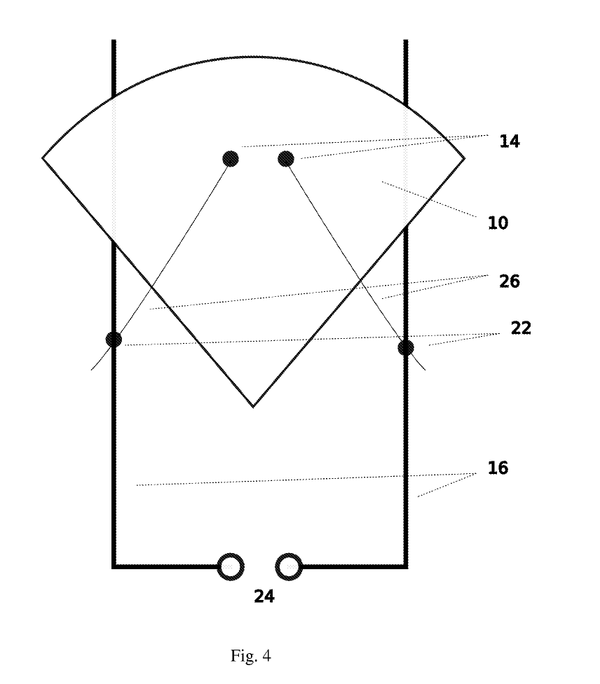

One of the examples of mounting the LED die 10 on the current carrying wires is illustrated by FIG. 4. The LED die 10, having a typical shape of a circle sector, is mechanically attached to the wires 16 connected to the external current source 24, while additional wires 26 are used for electrical connection between the said mechanically supporting wires 16 through the contacts 22, and individual LED devices formed on the said LED die 10. The typical length and width of the die can be in the range from 10 μm×10 μm to 20 cm×20 cm, including the embodiment there the said length and the said width are of distinctly different measures, forming a long narrow stripe or a wire-like structure within the said size range. As an additional embodiment to the present invention, a nano-dimensional object, such as carbon nanotube, a graphene-like sheet or the like can be mounted as described above.

There can be one or more LEDs on one LED die. The LEDs on one die can be connected directly on the die, or with external wires attached to them, for example soldered, bonded, glued, or similar.

Cooling of the LED dies is accomplished either by convection cooling, externally generated gas flow cooling or cooling through the thermal conduction from the LEDs through the substrate and through the wires attached to the substrate, or a combination thereof. Convection cooling can occur inside an enclosure, including but not limited to a glass bulb, or convection can be enhanced by making holes in the enclosure, so that gas (normally: air) can circulate into and out of the enclosure. External cooling can be realized as flowing gas cooling where cooling gas is flowing along one or more surfaces of the LED die to remove heat from there. High efficiency LEDs reduce the need for cooling further, because less heat is produced in the first place. Operation at low driving currents also reduces the cooling problem.

As another embodiment of the present invention, the efficiency of the LED die can be improved, so no external cooling is necessary.

The LED dies can produce the light output of different colors. They can be combined to generate single-, multi-colored, or white light. The bulb body 12 can be used for the LED die output of limited wavelength range conversion to the white light, for example by use of phosphors or other light-converting coating, or being itself made of light-converting material.

The LED die can make use of internal reflectors or other extraction-enhancements, like mirrors, substrate deposited lenses, optical resonators, internal reflection guiding, or diffraction patterns.

Although FIGS. 1-4 schematically show only one type of bulb body, it is understood that any bulb geometry suitable for use in replacement of existing light-sources or later developed by skilled artisan, as well as no bulb body can be used with respect to the current invention.

What is claimed is:

1. A light source comprising one or more light emitting device dies, where at least one of the said dies is mechanically mounted to the support element or elements that do not overlap the light paths for the emitted light coming out of any portion of the die, neither any significant fraction of any of the said light paths thereof.

2. A light source of claim 1, where the said light emitting device die comprises layers of semiconductor materials.

3. A light source as in claim 2, where the said light emitting device die further comprises one or more nano-dimensional structures and/or one or more graphene-like sheets.

4. A light source of claims 1-3, where at least one of the said support elements comprises electrical connection to the said light emitting device die.

5. A light source as in the claim 4, where at least one of the said support elements is an electrical current carrying wire that contacts the light emitting device contact pads comprised in the said light emitting device die.

6. A light source as in claims 1-3, where the light source is a fixture compatible with existing light bulb sockets both mechanically and electrically, so that the said light source can be used as a replacement for the light bulb in any or particular lighting applications.

7. A light source as in claim 6, where the said light emitting device die has the length and the width of distinctly different measures, so that it occupies a volume and position within a said conventional light bulb essentially similar to the volume and position occupied by a conventional light bulb filament.
